(19) United States
(12) Patent Application Publication
(10) Pub. No.: US 2009/0160054 A1
(43) Pub. Date: Jun. 25, 2009

(54) NITRIDE SEMICONDUCTOR DEVICE AND METHOD OF MANUFACTURING THE SAME

(75) Inventors: Katsuomi Shiozawa, Tokyo (JP); Kyozo Kanamoto, Tokyo (JP); Toshiyuki Oishi, Tokyo (JP); Yoichiro Tarui, Tokyo (JP); Yasunori Tokuda, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 12/269,914

(22) Filed: Nov. 13, 2008

(30) Foreign Application Priority Data
Dec. 20, 2007 (JP) 2007-328450

(51) Int. Cl. H01L 21/283; H01L 29/45

(52) U.S. Cl. 257/745; 438/656; 257/E29.144; 257/E21.159

(57) ABSTRACT

A nitride semiconductor device is provided which reduces the contact resistance at the interface between a P-type electrode and a nitride semiconductor layer. A nitride semiconductor device includes a P-type nitride semiconductor layer and a P-type electrode formed on the P-type nitride semiconductor layer. The P-type electrode is formed by successive laminations of a metal layer of a metal having a work function of 5.1 eV or more, a Pd layer of palladium, and a Ta layer of tantalum on the P-type nitride semiconductor layer.

### BACKGROUND OF THE INVENTION

1. Field of the Invention

The present invention relates to nitride semiconductor devices that are applicable to semiconductor laser diodes or the like, and in particular to the techniques for improving the contact resistance at the interface between a P-type electrode and a nitride semiconductor layer.

2. Description of the Background Art

Nitride semiconductor devices are generally manufactured by forming a P-type electrode on a nitride semiconductor layer such as a P-type GaN. Conventional nitride semiconductor devices employ nickel (Ni) or platinum (Pt) as the material for a P-type electrode (refer to, for example, Japanese Patent Application Nos. 8-160886 and 9-108673).

The use of Ni or Pt as the material for a P-type electrode, as described above, increases the difference in work function between the P-type electrode and a nitride semiconductor layer, so that the contact resistance at the interface between the P-type electrode and the nitride semiconductor layer is not sufficiently low.

Because of this, when conventional nitride semiconductor devices are used in manufacture of, for example, semiconductor laser diodes, there is the drawback that the operating voltages of the semiconductor laser diodes increase and the characteristics thereof vary due to heat generation during operation, which makes it difficult to provide stable operation within a specified temperature range.

### SUMMARY OF THE INVENTION

It is an object to provide a nitride semiconductor device that reduces the contact resistance at the interface between a P-type electrode and a nitride semiconductor layer.

A nitride semiconductor device according to the invention includes a P-type nitride semiconductor layer and a P-type electrode formed on the P-type nitride semiconductor layer. The P-type electrode is formed by successive laminations of a metal layer of a metal having a work function of 5.1 eV or more, a Pd layer of palladium (Pd), and a Ta layer of tantalum (Ta) on the P-type nitride semiconductor layer.

This device permits a greater reduction in the contact resistance at the interface between the P-type electrode and the P-type nitride semiconductor layer.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross-sectional view of a nitride semiconductor device 10 according to a first preferred embodiment;

FIG. 2 illustrates that a mask 5 is selectively formed on a P-type nitride semiconductor layer 1;

FIG. 3 illustrates that a metal layer 3a, a Pd layer 3b, and a Ta layer 3c are successively laminated on the P-type nitride semiconductor layer 1;

FIG. 4 illustrates that a P-type electrode 3 is formed on the P-type nitride semiconductor layer 1;

FIG. 5 shows a modification of the metal layer 3a (which is interspersed like islands); and

FIG. 6 is a schematic cross-sectional view of a light-emitting nitride semiconductor device 35 according to a third preferred embodiment.

### DESCRIPTION OF THE PREFERRED EMBODIMENTS

### First Preferred Embodiment

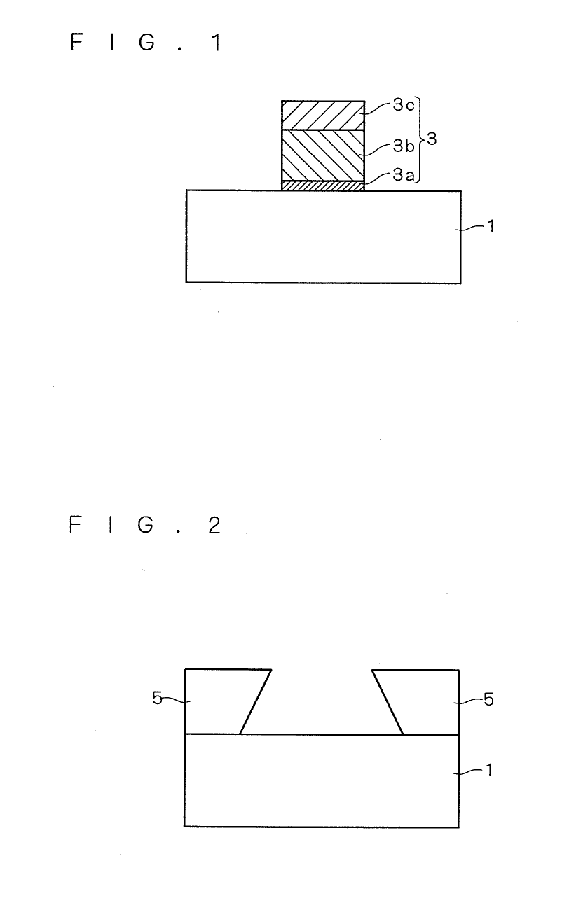

A nitride semiconductor device 10 according to the present preferred embodiment, as shown in FIG. 1, includes a P-type nitride semiconductor layer (P-type contact layer) of, for example, P-type AlₓGa₁₋ₓN (0≦x≦1), and a P-type electrode 3 selectively formed on the nitride semiconductor layer 1. The P-type electrode 3 is formed by successive laminations of a metal layer 3a of a metal (e.g., platinum (Pt)) having a work function of 5.1 eV or more, a Pd layer 3a of palladium (Pd), and a Ta layer 3b of tantalum (Ta) on the nitride semiconductor layer 1.

The metal layer 3a is for facilitating an ohmic contact with the P-type nitride semiconductor layer 1 at the interface. The Pd layer 3b is for transforming the surface of the P-type nitride semiconductor layer 1 to exhibit ohmic behavior. The Ta layer 3c is for inhibiting cohesion of the Pd layer 3b during the heat treatment of the P-type electrode 3 and promoting the above transformation of the surface of the P-type nitride semiconductor layer 1 for ohmic behavior.

Next, a method of manufacturing this nitride semiconductor device 10 is described.

First, as shown in FIG. 2, the P-type nitride semiconductor layer 1 is formed of P-type AlₓGa₁₋ₓN (0≦x≦1). Then, a mask 5 for use in the formation of the P-type electrode 3 is selectively formed on the nitride semiconductor layer 1.

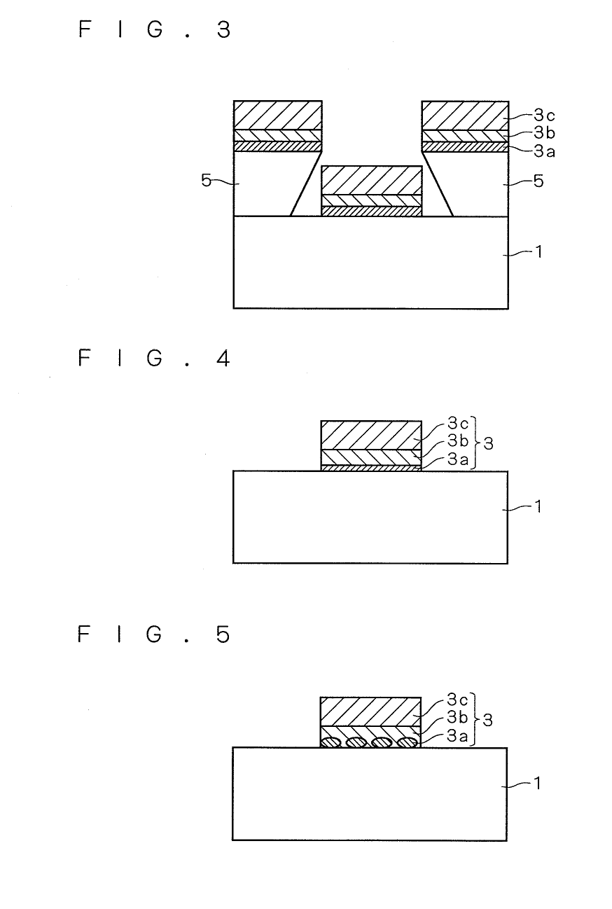

On the mask 5 and on the nitride semiconductor layer 1, as shown in FIG. 3, the metal layer (Pt layer in the present example) 3a, the Pd layer 3b, and the Ta layer 3c are deposited in layers by electron-beam (EB) evaporation or sputtering. At this time, the metal layer 3a is formed to such a uniform thickness (e.g., 10 nm or less) that will not influence the transforming effect that the Pd layer 3b and the Ta layer 3c formed on the metal layer 3a have on the surface of the P-type nitride semiconductor layer 1. The Pd layer 3b and the Ta layer 3c each are formed to a thickness of, for example, 10 to 100 nm (in the present example, the Pd layer 3b has a thickness of about 55 nm, and the Ta layer 3c has a thickness of about 15 nm.)

Then, as shown in FIG. 4, the mask 5 is removed by a lift-off method to remove unnecessary parts of the metal layer 3a, the Pd layer 3b, and the Ta layer 3c so as to selectively form the P-type electrode 3 on the nitride semiconductor layer 1. The P-type electrode 3 is then thermally processed to yield lower contact resistance.

For desired contact resistance, the heat treatment of the P-type electrode 3 after the formation of the P-type electrode 3, as described above, is necessary. This heat treatment should desirably be performed in an atmosphere containing oxygen, more specifically, in an atmosphere containing a gas such as air, oxygen (O₂), ozone (O₃), nitrogen monoxide (NO), nitrogen dioxide (NO₂), carbon monoxide (CO), carbon dioxide (CO₂), and water vapor (H₂O). The processing temperature at this time should desirably be on the order of, for example, 400 to 800° C.; it shall be any suitable temperature according to the material for the P-type electrode 3 or the like.

After the formation of the P-type electrode 3, a pad electrode (not shown) for use in wire bonding or the like is formed on the P-type electrode 3. Like the P-type electrode 3, the pad electrode can be formed by EB evaporation or sputtering. The material for the pad electrode should desirably be a material containing titanium (Ti), and specific examples of the material include Ti, Ta, gold (Au), and molybdenum (Mo). Specific examples of the structure of the pad electrode include a Ti/Ta/Ti/Au layered structure and a Ti/Mo/Ti/Au layered structure. The thickness of the pad electrode may vary depending on the processing performed after the formation of the pad electrode. Through the process described above, the nitride semiconductor device 10 is manufactured.

The nitride semiconductor device 10 manufactured in this way has the following advantages. Firstly, since the P-type electrode 3 includes the Pd layer 3b and the Ta layer 3c, the surface of the P-type nitride semiconductor layer 1 can be transformed to exhibit ohmic behavior by the transforming effect of these layers 3b and 3c. Secondly, the intervention of the metal layer 3a of a metal having a work function of 5.1. eV or more at the interface between the P-type electrode 3 and the P-type nitride semiconductor layer 1 allows a further reduction than ever in the work-function difference between the P-type electrode 3 and the P-type nitride semiconductor device 1. These advantages permit a greater reduction in the contact resistance at the interface between the P-type electrode 3 and the P-type nitride semiconductor layer 1. This consequently prevents an increase in the operating voltage of the nitride semiconductor device 10 and reduces the influence of heat generation during operation, thereby allowing stable and high-power operation output.

Generally in P-type nitride semiconductor devices, for good ohmic behavior at the interface between a P-type electrode and a P-type nitride semiconductor layer, the P-type electrode must be formed of a metal that has a higher work function than the P-type nitride semiconductor layer. The P-type nitride semiconductor layer, however, has a work function as high as 7.5 eV, so that there is no metal that can make an easy ohmic contact with such a P-type nitride semiconductor layer. Thus, according to the invention, the metal layer 3a of a metal having a work function of 5.1 eV or more is provided to intervene between the P-type nitride semiconductor layer 1 and the Pd layer 3b so as to narrow the difference in work function between the P-type electrode 3 and the P-type nitride semiconductor layer 1 and to thereby reduce the contact resistance at the interface between the P-type electrode 3 and the P-type nitride semiconductor layer 1 more than ever before.

Since the metal layer 3a is formed uniformly throughout the interface between the Pd layer 3b and the P-type nitride semiconductor layer 1, the contact resistance at the interface between the P-type electrode 3 and the P-type nitride semiconductor layer 1 can be reduced uniformly.

The metal layer 3a with a thickness of 10 nm or less can effectively reduce the contact resistance at the interface between the P-type electrode 3 and the P-type nitride semiconductor layer 1 without inhibiting the transforming effect of the Pd layer 3b and the Ta layer 3c that transform the surface of the P-type nitride semiconductor layer 1 to exhibit ohmic behavior.

The manufacturing method described above includes the step of forming the P-type electrode 3 by successive laminations of the metal layer 3a of a metal having a work function of 5.1 eV or more, the Pd layer 3b, and the Ta layer 3c on the P-type nitride semiconductor layer 1; and the step of thermally processing the P-type electrode 3. This method provides a nitride semiconductor device with lower contact resistance than ever at the interface between the P-type electrode 3 and the P-type nitride semiconductor layer 1.

The heat treatment of the P-type electrode 3 is performed in an atmosphere containing an oxygen-molecule-containing or oxygen-atom-containing gas. This effectively reduces the contact resistance at the interface between the P-type electrode 3 and the P-type nitride semiconductor layer 1.

While, in the present preferred embodiment, platinum (Pt) is used as a metal having a work function of 5.1 eV or more, the invention is not limited thereto. For instance, nickel (Ni) or iridium (Ir) will have the same effect.

### Second Preferred Embodiment

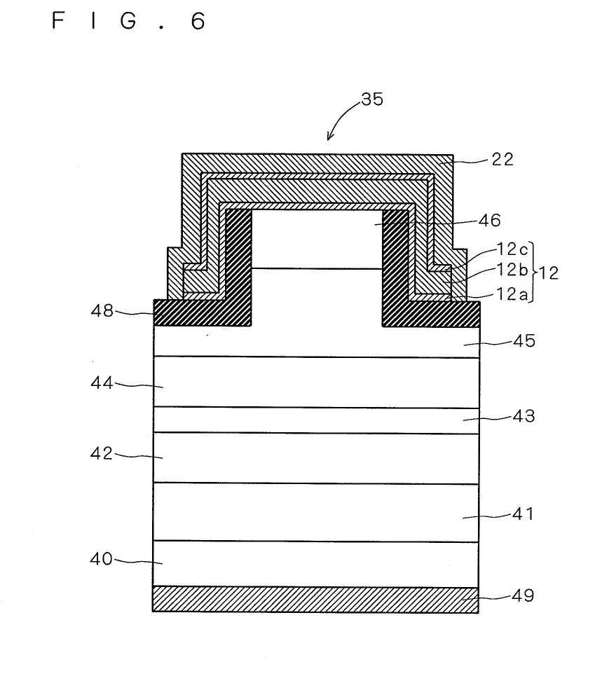

While the metal layer 3a in the first preferred embodiment is formed uniformly, it may be, as shown in FIG. 5, formed in part (e.g., interspersed like islands) between the Pd layer 3b and the P-type nitride semiconductor layer 1.

By so doing, the contact resistance at the interface between the P-type electrode 3 and the P-type nitride semiconductor layer 1 can effectively be reduced with the presence of the metal layer 3a, and in the places where the metal layer 3a is not present, the transforming effect of the Pd layer 3b and the Ta layer 3c is directly exerted on the P-type nitride semiconductor layer 1, which further promotes the transformation of the surface of the P-type nitride semiconductor layer 1 for ohmic behavior.

### Third Preferred Embodiment

A third preferred embodiment describes a light-emitting nitride semiconductor device 35 that applies the nitride semiconductor devices 10 according to the first and second preferred embodiments. FIG. 6 is a schematic cross-sectional view of the light-emitting nitride semiconductor device 35. The light-emitting nitride semiconductor device 35 is formed using an n-type gallium nitride (GaN) substrate 40 which is a nitride semiconductor substrate.

On the n-type GaN substrate 40, a layered structure of nitride semiconductors is formed. More specifically, an n-type AlGaN clad layer 41, an n-type GaN guide layer 42, an active layer 43, a P-type GaN guide layer 44, a P-type AlGaN clad layer 45, and a P-type GaN contact layer (P-type nitride semiconductor layer) 46 are formed in order of mention on the n-type GaN substrate 40.

The n-type GaN substrate 40 and the layered structure form a semiconductor laser diode. The P-type electrode 12 is formed on the P-type GaN contact layer 46, and a pad electrode 22 is formed on this P-type electrode 12. The P-type AlGaN clad layer 45 and the P-type GaN contact layer 46 are patterned into a given shape by etching. The P-type electrode 12 is formed of a metal layer 12a of a metal (e.g., Ni, Pt, or Ir) having a work function of 5.1 eV or more, a Pd layer 12b of palladium (Pd), and a Ta layer 12c of tantalum (Ta). The metal layer 12a, the Pd layer 12b, and the Ta layer 12c are formed in order of mention on the P-type GaN contact layer 46.

The metal layer 12a is for facilitating an ohmic contact with the P-type GaN contact layer 46 at the interface. The Pd layer 12b is for transforming the surface of the P-type GaN contact layer 46 to exhibit ohmic behavior. The Ta layer 12c is for inhibiting cohesion of the Pd layer 12b during the heat treatment of the P-type electrode 12 and promoting the above transformation of the surface of the P-type GaN contact layer 46 for ohmic behavior.

Further, an SiO₂ film 48 is formed as a protective film on a part of the surface of the P-type AlGaN clad layer 45. Still further, an n electrode 49 is formed as a metal electrode on the underside of the n-type GaN substrate 40.

In the light-emitting nitride semiconductor device 35 manufactured in this way, since as in the case of the first preferred embodiment, the P-type electrode 12 includes the Pd layer 12b and the Ta layer 12c, the surface of the P-type GaN contact layer 46 can be transformed to exhibit ohmic behavior by the transforming effect of these layers 12b and 12c, and besides, the intervention of the metal layer 12a of a metal having a work function of 5.1. eV or more at the interface between the P-type electrode 12 and the P-type GaN contact layer 46 allows a further reduction than ever in the work-function difference between the P-type electrode 12 and the P-type GaN contact layer 46. These advantages permit a greater reduction in the contact resistance at the interface between the P-type electrode 12 and the P-type GaN contact layer 46. This consequently prevents an increase in the operating voltage of the light-emitting nitride semiconductor device 35 and reduces the influence of heat generation during operation, thereby allowing stable and high-power operation output.

While the invention has been shown and described in detail, the foregoing description is in all aspects illustrative and not restrictive. It is therefore understood that numerous modifications and variations can be devised without departing from the scope of the invention.

What is claimed is:

1. A nitride semiconductor device comprising:
a P-type nitride semiconductor layer; and
a P-type electrode formed on said P-type nitride semiconductor layer,
said P-type electrode being formed by successive laminations of a metal layer of a metal having a work function of 5.1 eV or more, a Pd layer of palladium (Pd), and a Ta layer of tantalum (Ta) on said P-type nitride semiconductor layer.

2. The nitride semiconductor device according to claim 1, wherein
said metal layer is formed of any one of nickel (Ni), platinum (Pt), and iridium (Ir).

3. The nitride semiconductor device according to claim 1, wherein
said metal layer is formed uniformly throughout the interface between said Pd layer and said P-type nitride semiconductor layer.

4. The nitride semiconductor device according to claim 1, wherein
said metal layer has a thickness of 10 nm or less.

5. The nitride semiconductor device according to claim 1, wherein
said metal layer is formed in part between said Pd layer and said P-type nitride semiconductor layer.

6. A method of manufacturing a nitride semiconductor device, comprising the steps of:
forming a P-type electrode by successive laminations of a metal layer of a metal having a work function of 5.1 eV or more, a Pd layer of palladium (Pd), and a Ta layer of tantalum (Ta) on a P-type nitride semiconductor layer; and
performing heat treatment of said P-type electrode.

7. The method of manufacturing a nitride semiconductor device according to claim 6, wherein
said heat treatment is performed in an atmosphere containing an oxygen-molecule-containing or oxygen-atom-containing gas.
